(19) United States
(12) Patent Application Publication
(10) Pub. No.: US 2007/0268059 A1
(43) Pub. Date: Nov. 22, 2007

(54) SEMICONDUCTOR INTEGRATED CIRCUIT DEVICE

(75) Inventors: Tomohisa SAKAGUCHI, Osaka (JP); Hiroki Matsunaga, Osaka (JP); Akihiro Maejima, Osaka (JP); Jinsaku Kaneda, Osaka (JP); Eisaku Maeda, Osaka (JP)

Correspondence Address: RATNERPRESTIA, P.O. BOX 980, VALLEY FORGE, PA, 19482, US

(73) Assignee: Matsushita Electric Industrial Co., Ltd., Osaka (JP)

(21) Appl. No.: 11/749,266

(22) Filed: May 16, 2007

(30) Foreign Application Priority Data
May 17, 2006 (JP) 2006-137434

(51) Int. Cl. H03L 5/00

(52) U.S. Cl. 327/333

(57) ABSTRACT

A semiconductor integrated circuit device capable of securely preventing the output from becoming indefinite even when power is turned ON or OFF or even in a transient state in which the power voltage varies abruptly. In the semiconductor integrated circuit device, a protection circuit compares the power voltage from a first power supply terminal with a reference voltage, detects power ON, power OFF and abrupt power voltage variation, and outputs a reset command signal so that the output at the output terminal has a high impedance at the time of power ON, power OFF and abrupt power voltage variation.

### BACKGROUND OF THE INVENTION

The present invention relates to a semiconductor integrated circuit device having a protection circuit for stabilizing the output, and more particularly, to a semiconductor integrated circuit device being used as a drive circuit for plasma display panels (hereafter abbreviated as “PDPs”) and the like.

Conventionally, as this kind of technology, the technology described in Japanese Patent Application Laid-Open Publication No. 2004-12535 is known. FIG. 16 is a view showing the configuration of a PDP driver described in Japanese Patent Application Laid-Open Publication No. 2004-12535. As shown in FIG. 16, the PDP driver 100 described in Japanese Patent Application Laid-Open Publication No. 2004-12535 has a control circuit 102 for generating a control signal for controlling the output state using a low voltage, and an output circuit 101 for outputting a high voltage depending on the control signal generated from the control circuit 102. The control circuit 102 is provided with a forced reset circuit 103 for forcibly setting the output of the output circuit 101 to a high impedance state when low voltage power is turned ON or OFF.

As described above, the conventional PDP driver is provided with the forced reset circuit for forcibly setting the output of the output circuit to a high impedance state when the low voltage power is turned ON or OFF to prevent the output of the output circuit from becoming indefinite. However, in a transient state in which the low voltage power is changed from OFF to ON, the forced reset circuit does not operate. Hence, there is a period during which the output of the output circuit is indefinite. Consequently, the conventional PDP drive circuit has a problem of generating image disturbance depending on the state of the load in the transient state described above.

### SUMMARY OF THE INVENTION

The present invention is intended to solve the problem encountered in the conventional technology described above and to provide a semiconductor integrated circuit device capable of securely preventing the output of its output circuit from becoming indefinite even when power is turned ON or OFF or even in a transient state in which the power voltage varies.

For the purpose of attaining the above-mentioned object, a semiconductor integrated circuit device according to the present invention comprises:

a protection circuit for comparing a power voltage from a first power supply terminal with a reference voltage, for detecting power ON, power OFF and power voltage variation and for outputting a reset command signal so that the output at an output terminal has a high impedance at the time of power ON, power OFF and power voltage variation,

a control circuit, connected to the first power supply terminal, for receiving the reset command signal from the protection circuit and a control signal from a control signal input terminal and for generating drive signals, and

an output circuit, having a push-pull circuit and a level shift circuit comprising multiple MOS transistors and driven using the drive signals from the control circuit, for generating an output signal from the output terminal, wherein

the protection circuit, the control circuit and the output circuit are integrated in a single semiconductor chip. In the semiconductor integrated circuit device according to the present invention configured as described above, any period during which the output of the output circuit becomes indefinite can be eliminated when power is turned ON or OFF, or in a transient state in which the power voltage varies.

The semiconductor integrated circuit device according to the present invention may have a configuration wherein the protection circuit is connected between the first power supply terminal and a ground side terminal and has a voltage division circuit formed of multiple resistors for dividing the power voltage of the first power supply terminal, a comparator for comparing the divided voltage being input thereto with the reference voltage inside the protection circuit, and a hysteresis generating circuit connected across both terminals of at least one resistor of the voltage division circuit, the output of the comparator serving as a reset command signal. In the semiconductor integrated circuit device according to the present invention configured as described above, the output can be stabilized, and improper operation of the protection circuit can be prevented.

The semiconductor integrated circuit device according to the present invention may have a configuration wherein the division circuit comprises at least a first resistor, a second resistor and a third resistor, one terminal of the first resistor is connected to the ground side terminal, one terminal of the third resistor is connected to the first power supply terminal, the comparator compares the voltage of the connection point of the first resistor and the second resistor with the reference voltage inside the protection circuit, and the hysteresis generating circuit comprises a P-channel MOS transistor, the source of which is connected to the first power supply terminal, the drain of which is connected to the connection point of the second resistor and the third resistor, and the gate of which is connected to the output of the comparator. In the semiconductor integrated circuit device according to the present invention configured as described above, the output can be stabilized, and improper operation of the protection circuit can be prevented.

The semiconductor integrated circuit device according to the present invention may have a configuration wherein the output circuit is connected to a second power supply terminal having a voltage higher than that of the first power supply terminal. The semiconductor integrated circuit device according to the present invention configured as described above can be used for high voltage loads, thereby serving as a highly versatile device.

The semiconductor integrated circuit device according to the present invention may have a configuration wherein a resistor having a predetermined resistance value is provided between the output of the protection circuit and the ground side terminal. In the semiconductor integrated circuit device according to the present invention configured as described above, in a transient state in which the power voltage varies abruptly, any period during which the output of the output circuit becomes indefinite can be eliminated.

The semiconductor integrated circuit device according to the present invention may have a configuration wherein the reference voltage that is input to the comparator has the threshold value of an N-channel MOS transistor, the drain and gate of which are connected to each other. In the semiconductor integrated circuit device according to the present invention configured as described above, the circuit for generating the reference voltage is made simple, thereby being suited for chip shrinkage.

The semiconductor integrated circuit device according to the present invention may have a configuration wherein a resistor is provided between the gate of the P-channel MOS transistor of the hysteresis generating circuit and the output of the comparator. In the semiconductor integrated circuit device according to the present invention configured as described above, the protection circuit securely operates, for example, when the power voltage rises abruptly, thereby being capable of preventing the output from becoming indefinite.

The semiconductor integrated circuit device according to the present invention may have a configuration wherein an analog switch circuit having a control terminal is provided between the first power supply terminal and the power input side of the protection circuit. In the semiconductor integrated circuit device according to the present invention configured as described above, the output can be stabilized, and any abnormal leak current in the control circuit can be detected easily.

The semiconductor integrated circuit device according to the present invention may have a configuration wherein the analog switch circuit comprises a P-channel MOS transistor, the source of which is connected to the first power supply terminal, the drain of which is connected to the power input side of the protection circuit, and the gate of which is connected to the control terminal. In the semiconductor integrated circuit device according to the present invention configured as described above, any abnormal leak current in the control circuit can be detected easily.

The semiconductor integrated circuit device according to the present invention may have a configuration wherein the analog switch circuit comprises two P-channel MOS transistors, the source of a first P-channel MOS transistor is connected to the first power supply terminal, the drain of the first P-channel MOS transistor is connected to the drain of a second P-channel MOS transistor, the source of the second P-channel MOS transistor is connected to the power input side of the protection circuit, and the gates of the first P-channel MOS transistor and the second P-channel MOS transistor are connected to the control terminal. In the semiconductor integrated circuit device according to the present invention configured as described above, reverse current flow from the protection circuit to the first power supply terminal can be prevented even when the voltage of the protection circuit rises.

The semiconductor integrated circuit device according to the present invention can securely prevent the output of the output circuit from becoming indefinite when power is turned ON or OFF, or in a transient state in which the power voltage varies abruptly. The semiconductor integrated circuit device according to the present invention has a configuration wherein a resistor is provided between the ground side terminal and the output of the protection circuit operating at a low voltage and the protection circuit operates when power is turned ON or OFF or in a transient state in which the power voltage varies abruptly. Hence, the semiconductor integrated circuit device has an excellent effect capable of eliminating any period during which the output thereof becomes indefinite.

### BRIEF DESCRIPTION OF THE DRAWINGS

FIG. 1 is a view showing the configuration of a PDP driver serving as a semiconductor integrated circuit device according to a first embodiment of the present invention;

FIG. 2 is a view showing a configuration for describing a problem encountered in the PDP driver according to the first embodiment of the present invention;

FIGS. 3A to 3F show signal waveforms at various portions of the PDP driver according to the first and second embodiments of the present invention;

FIG. 4 is a view showing the configuration of a PDP driver serving as a semiconductor integrated circuit device according to the second embodiment of the present invention;

FIG. 5 is a block diagram showing the configuration of the PDP driver according to the second embodiment;

FIG. 6 is a circuit diagram showing a specific circuit of the PDP driver according to the second embodiment;

FIG. 7 is a circuit diagram showing the configuration of the reference voltage generating circuit of a protection circuit in the PDP driver according to the second embodiment;

FIG. 8 is a block diagram showing the configuration of a PDP driver according to a third second embodiment;

FIG. 9 is a circuit diagram showing a specific circuit of the PDP driver according to the third embodiment;

FIG. 10 is a block diagram showing the configuration of a PDP driver according to a fourth embodiment;

FIG. 11 is a circuit diagram showing the configuration of an analog switch circuit 14 in the PDP driver according to the fourth embodiment;

FIG. 12 is a circuit diagram showing a specific circuit of the PDP driver according to the fourth embodiment including the analog switch circuit 14 shown in FIG. 11;

FIG. 13 is a circuit diagram showing an analog switch circuit 14A having another configuration in the PDP driver according to the fourth embodiment;

FIG. 14 is a circuit diagram showing the PDP driver according to the fourth embodiment including the analog switch circuit 14A shown in FIG. 13;

FIG. 15 is a block diagram showing still another configuration of the semiconductor integrated circuit device according to the fourth embodiment; and

FIG. 16 is a view showing the configuration of the conventional PDP driver.

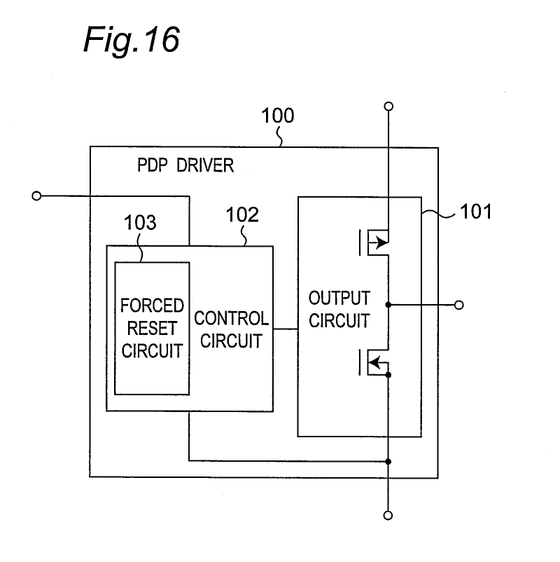

### DETAILED DESCRIPTION OF THE PREFERRED EMBODIMENTS

Preferred Embodiments of a semiconductor integrated circuit device according to the present invention will be described below referring to the accompanying drawings.

### First Embodiment

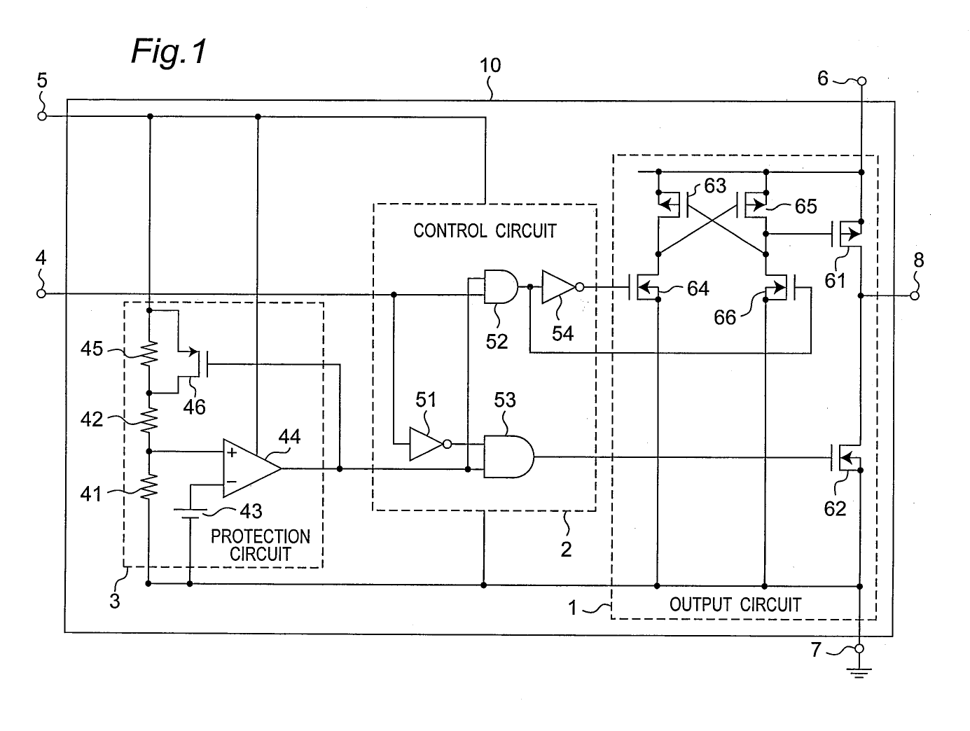

In a semiconductor integrated circuit device according to a first embodiment of the present invention, a PDP driver serving as a circuit for driving plasma display panels (PDPs) will be described as an example of the semiconductor integrated circuit device. FIG. 1 is a view showing the configuration of the PDP driver according to the first embodiment.

As shown in FIG. 1, the PDP driver 10 is provided with a control circuit 2 connected to a control signal input terminal 4 to which a control signal is input and to a first power supply terminal 5 to which low voltage power is input; an output circuit 1 to which drive signals from the control circuit 2 are input and from which the output to an output terminal 8 is generated; and a protection circuit 3 for preventing the output of this output circuit 1 from becoming indefinite. The control circuit 2, comprising MOS transistors, carries out logical operation depending on the control signal from the control signal input terminal 4 and generates the drive signals for drive-controlling the output circuit 1 using the low voltage power supplied from the first power supply terminal 5 through which power is turned ON or OFF. The output circuit 1 has a push-pull circuit comprising a P-channel MOS transistor 61 and an N-channel MOS transistor 62 to which high voltage power is supplied from a second power supply terminal 6 and a level shift circuit comprising N-channel MOS transistors 64 and 66 and P-channel MOS transistor 63 and 65. The push-pull circuit comprising the P-channel MOS transistor 61 and the N-channel MOS transistor 62 is connected to the output terminal 8 and drives the capacitance load of a PDP. In addition, the ground side of the push-pull circuit is connected to a third power supply terminal 7. In the first embodiment shown in FIG. 1, the output circuit 1 having the series circuit of the P-channel MOS transistor 61 and the N-channel MOS transistor 62 is shown as an example. However, the present invention is not limited to this kind of combination. For example, the output circuit may have a configuration wherein the P-channel MOS transistor 61 is replaced with the N-channel MOS transistor 62.

In the first embodiment, the protection circuit 3 is a UVLO (under-voltage lock-out) circuit and detects voltage variation at the first power supply terminal 5 when the sequence of power ON and OFF through the first power supply terminal 5 and the second power supply terminal 6 is changed improperly or when the power voltage at the first power supply terminal 5 drops (lowers). The voltage at the first power supply terminal 5 is divided using a voltage division circuit comprising resistors 41, 42 and 45 connected in series. The divided voltage at the connection point of the resistors 41 and 42 is compared with the reference voltage 43 of the protection circuit 3 using a comparator 44. The protection circuit 3 forcibly sets the output at the output terminal 8 to a high impedance state, for example, when the sequence of power ON and OFF through the first power supply terminal 5 and the second power supply terminal 6 is different from the proper sequence. Furthermore, when an abnormality is detected in the power supply sequence or the like, the protection circuit 3 outputs a reset command signal to the control circuit 2 so that the state at the output terminal 8 is forcibly switched to a safe state (high impedance state).

The semiconductor integrated circuit device according to the first embodiment operates as described below. The control circuit 2 outputs low-voltage drive signals to the output circuit 1 at a timing when the gate terminals of the MOS transistors 61 and 62 are not turned ON simultaneously and when no flow-through current is generated between the second power supply terminal 6 to which a high voltage is applied and a third power supply terminal 7 serving as a ground side terminal. The output circuit 1 to which the drive signals are input generates an output signal that is output from the output terminal 8 depending on the control signal.

In the semiconductor integrated circuit device according to the first embodiment, a hysteresis generating circuit comprising a P-channel MOS transistor 46 and the resistor 45 connected across the source and drain thereof is provided for the protection circuit 3 to generate hysteresis. This hysteresis generating circuit comprises the P-channel MOS transistor 46, the source of which is connected to the first power supply terminal 5, the drain of which is connected to the connection point of the resistor 42 and the resistor 45, and the gate of which is connected to the output of the comparator 44.

The semiconductor integrated circuit device according to the first embodiment configured as described above operates as described below. When power is turned ON or OFF at the first power supply terminal 5 or when the power voltage varies, the protection circuit 3 operates, and the output of the protection circuit 3 becomes LOW (low voltage). To the control circuit 2, the protection circuit 3 outputs a reset command signal to perform forcible switching so that periods during which the output from the output circuit 1 becomes indefinite are not generated.

In the semiconductor integrated circuit device according to the first embodiment, upon detecting voltage variation, the protection circuit 3 outputs the reset command signal to the control circuit 2. To prevent the P-channel MOS transistor 61 serving as a high-side switching device and the N-channel MOS transistor 62 serving as a low-side switching device from being overheated by a flow-through current, the control circuit 2 outputs gate signals so that both the switching devices (61, 62) become OFF. The control circuit 2 comprises MOS inverters 51 and 54 and AND circuits 52 and 53, and is connected to the first power supply terminal 5 from which a low voltage is input. Furthermore, to the control circuit 2, the control signal is input from the control signal input terminal 4, and the reset command signal is input from the protection circuit 3.

In the semiconductor integrated circuit device according to the first embodiment configured as described above, the output of the output circuit can be prevented from becoming indefinite even when power is turned ON or OFF or even in a transient state in which the power voltage varies.

### Second Embodiment

A semiconductor integrated circuit device according to a second embodiment of the present invention will be described below. The semiconductor integrated circuit device according to the second embodiment is a PDP driver serving as a circuit for driving plasma display panels (PDPs) and has a configuration obtained by further improving the configuration of the PDP driver according to the first embodiment described above.

In the configuration of the semiconductor integrated circuit device according to the first embodiment shown in FIG. 1 described above, in a transient period during which the state at the first power supply terminal 5 changes OFF to ON, the protection circuit 3 does not operate immediately. As a result, there is a period during which the output from the control circuit 2 becomes indefinite momentarily.

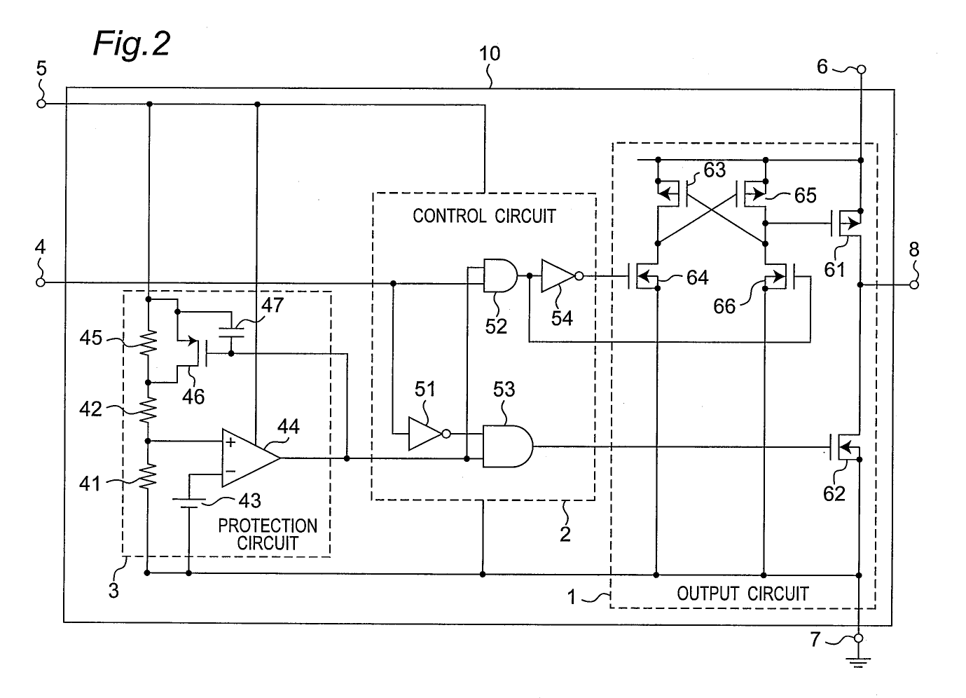

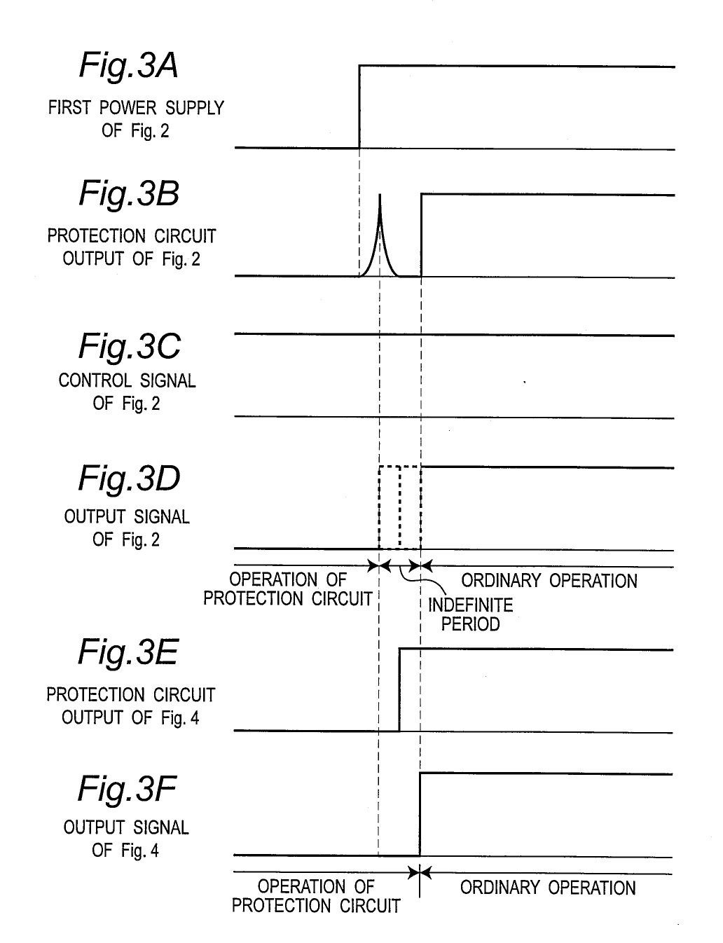

FIG. 2 is a view showing a configuration for describing a problem encountered in the PDP driver according to the first embodiment. FIGS. 3A to 3D show signal waveforms at various portions of the PDP driver according to the first embodiment. FIGS. 3E and 3F show signal waveforms in the PDP driver according to the second embodiment. FIG. 3B shows the output signal of the protection circuit 3, FIG. 3C shows the control signal from the control signal input terminal 4, and FIG. 3D shows the output signal from the output terminal 8 when the low voltage power at the first power supply terminal 5 shown in FIG. 3A changes from OFF to ON. FIG. 3B shows the waveform of the reset command signal serving as the output signal from the protection circuit 3, and FIG. 3D shows the waveform of the output signal from the output terminal 8 when the control signal from the control signal input terminal 4 is HIGH (high voltage) and when the state at the first power supply terminal 5 is changed from OFF to ON. The waveforms shown in FIG. 3A to 3D are output when the PDP driver configured as shown in FIG. 2 is used.

In a transient state in which the low voltage power at the first power supply terminal 5 is changed from OFF to ON, a signal having a differential waveform that rises abruptly as shown in FIG. 3B may be generated occasionally as the output signal of the protection circuit 3 owing to a parasitic capacitance 47 (see FIG. 2) across the source and the gate of the P-channel MOS transistor 46 because the output of the protection circuit 3 has a high impedance. If the signal having such a differential waveform is generated, the reset function of the protection circuit 3 for the control circuit 2 is disabled, and there occurs a period during which the voltage becomes indefinite and the protection circuit 3 is inoperative.

Hence, in the transient state in which the low voltage power at the first power supply terminal 5 is changed from OFF to ON, the LOW (low voltage) signal for forcibly setting the state at the output terminal 8 to a high impedance state is not output from the protection circuit 3, but the signal that is input from the control signal input terminal 4 has priority, regardless of the state of the control signal that is input from the control signal input terminal 4. As a result, there occurs a period during which the reset function of the protection circuit 3 is inoperative. Consequently, there occurs a period during which the waveform of the output at the output terminal 8 becomes indefinite momentarily.

The operation of the protection circuit 3 becomes stable gradually, and the reset function of the protection circuit 3 begins to become operative, whereby the output signal of the protection circuit 3 becomes LOW (low voltage). As a result, the output at the output terminal 8 has high impedance.

The semiconductor integrated circuit device according to the second embodiment of the present invention has a configuration in which the protection circuit 3 operates stably and securely, even if abrupt power ON or OFF occurs.

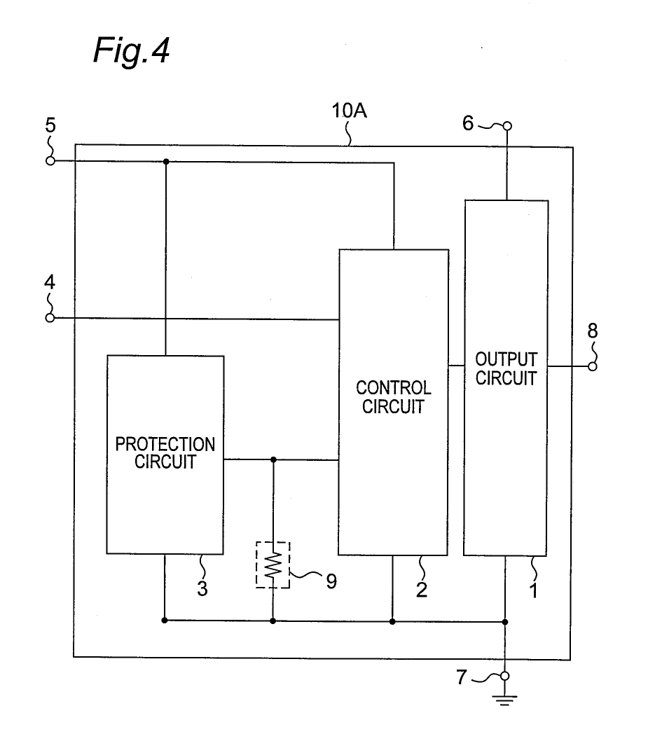

FIG. 4 is a view showing the configuration of a PDP driver 10A taken as an example of the semiconductor integrated circuit device according to the second embodiment of the present invention. The PDP driver 10A comprises the protection circuit 3 connected to the first power supply terminal 5; the control circuit 2, to which the reset command signal serving as the output signal of the protection circuit 3 is input, operating using the control signal from the control signal input terminal 4; and a pull-down resistor 9 provided between the output of the protection circuit 3 and the third power supply terminal 7 on the ground side. These components of the PDP driver 10A are integrated in a single semiconductor chip. The protection circuit 3 according to the second embodiment detects the variation of the voltage at the first power supply terminal 5 when the power voltage that is input from the first power supply terminal 5 drops (lowers).

In the PDP driver 10A according to the second embodiment, the pull-down resistor 9 is provided between the output of the protection circuit 3 and the third power supply terminal 7 on the ground side, whereby the signal having the differential waveform generated in the reset command signal owing to the parasitic capacitance 47 of the P-channel MOS transistor 46 can be suppressed.

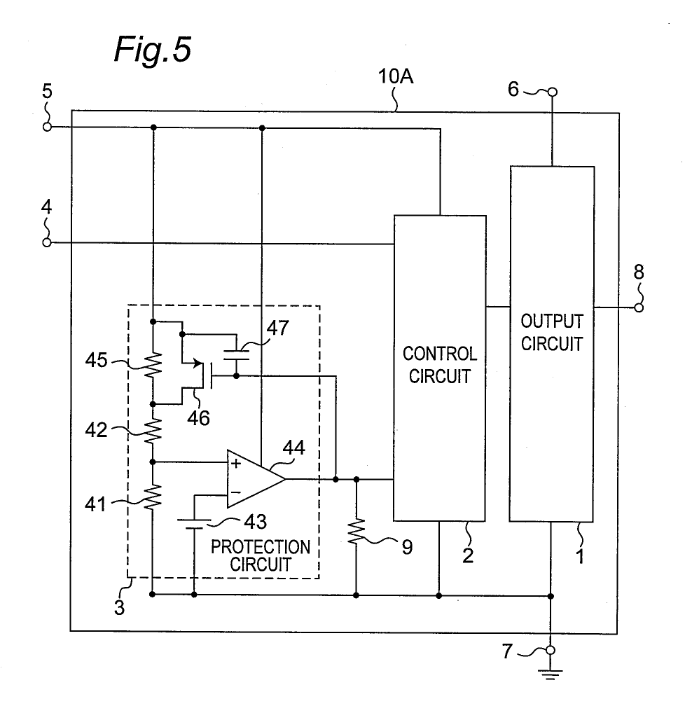

FIG. 5 is a view showing a specific configuration of the protection circuit 3 in the semiconductor integrated circuit device according to the second embodiment shown in FIG. 4. As shown in FIGS. 4 and 5, the PDP driver 10A serving as the semiconductor integrated circuit device according to the second embodiment is connected to two power supply terminals (the low-voltage power supply terminal 5 and the high-voltage power supply terminal 6) and to one ground side terminal 7 and drive-controlled, thereby outputting a PDP drive signal from the output terminal 8. The semiconductor integrated circuit device 10A according to the second embodiment comprises the protection circuit 3 connected to the first power supply terminal 5; the control circuit 2, to which the reset command signal serving as the output signal of the protection circuit 3 is input, for carrying out logical operation; the output circuit 1 having a push-pull circuit and a level shift circuit connected to the second power supply terminal 6 to which high voltage power is input and to the third power supply terminal 7 on the ground side, and connected to the output terminal 8; and the pull-down resistor 9 provided between the output of the protection circuit 3 and the third power supply terminal 7 on the ground side.

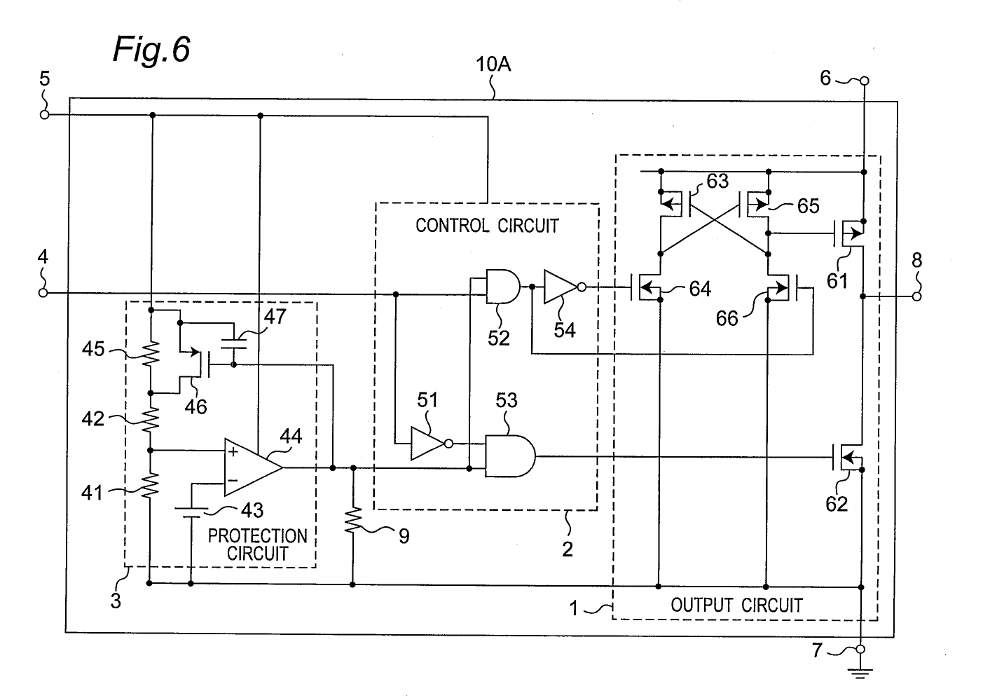

FIG. 6 is a circuit diagram showing a specific configuration of the PDP driver 10A according to the second embodiment. As shown in FIG. 6, the control circuit 2 comprises MOS transistors operating using the control signal from the control signal input terminal 4 and carries out logical operation. The output circuit 1 connected to the output terminal 8 has a push-pull circuit comprising a P-channel MOS transistor 61 connected to the second power supply terminal 6 and an N-channel MOS transistor 62 connected to the third power supply terminal 7 on the ground side and is drive-controlled using the drive signals from the control circuit 2. Furthermore, the output circuit 1 has a level shift circuit comprising N-channel MOS transistors 64 and 65 and P-channel MOS transistors 63 and 65.

In the second embodiment, the output circuit having the series circuit of the P-channel MOS transistor 61 and the N-channel MOS transistor 62 is taken as an example. However, the present invention is not limited to this combination. For example, the output circuit may have a configuration wherein the P-channel MOS transistor 61 is replaced with the N-channel MOS transistor 62.

As in the first embodiment, the protection circuit 3 in the second embodiment is a UVLO (under-voltage lock-out) circuit and detects voltage variation at the first power supply terminal 5 when the sequence of power ON and OFF through the first power supply terminal 5 and the second power supply terminal 6 is changed improperly or when the power voltage at the first power supply terminal 5 drops (lowers). The voltage varying at the first power supply terminal 5 is divided using resistors 41, 42 and 45. The divided voltage at the connection point of the resistors 41 and 42 is compared with the reference voltage 43 of the protection circuit 3 using a comparator 44.

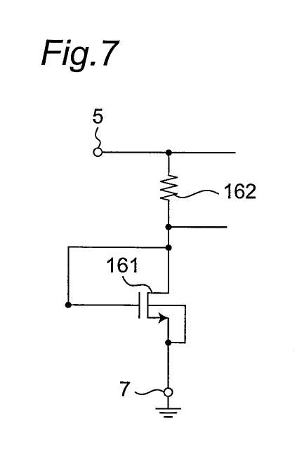

A band gap voltage that is used generally is used as the reference voltage 43 for use in the protection circuit 3 according to the second embodiment. However, the reference voltage may be generated using the threshold value of a MOS diode obtained by connecting the drain and the gate of an N-channel MOS transistor 161 as shown in FIG. 7. The drain of this N-channel MOS transistor 161 is connected to the comparator 44 and also connected to the first power supply terminal 5 via a resistor 162. This configuration is simpler than the circuit configuration for generating the band gap voltage, thereby being suited for chip shrinkage.

If the protection circuit 3 detects voltage variation, the protection circuit 3 outputs the reset command signal to the control circuit 2, and the control circuit 2 outputs gate signals to the high-side switching device and the low-side switching device so that both the switching devices are turned OFF and thus not overheated by a flow-through current.

In the protection circuit 3 according to the second embodiment, a hysteresis generating circuit comprises a resistor 45 and a P-channel MOS transistor 46 as shown in FIG. 6. The control circuit 2 comprises MOS inverters 51 and 54 and AND circuits 52 and 53. The control signal from the control signal input terminal 4 and the reset command signal from the protection circuit 3 are input to the control circuit 2. The output circuit 1 has a level shift circuit comprising N-channel MOS transistors 64 and 66 and P-channel MOS transistors 63 and 65.

Next, the operation of the PDP driver 10A serving as the semiconductor integrated circuit device according to the second embodiment will be described below. In the following description, “H” designates that a voltage has a HIGH (high voltage) level, and “L” designates that a voltage has a LOW (low voltage) level.

The output mode of the output terminal 8 is switched using the control signal from the control signal input terminal 4. When the control signal at the control signal input terminal 4 is “H” and when the reset command signal serving as the output signal of the protection circuit 3 is “H”, by virtue of the logic circuit comprising the MOS inverters 51 and 54 and the AND circuits 52 and 53, the voltages applied to the gates of the N-channel MOS transistors 62 and 64 become “L”, and the N-channel MOS transistors 62 and 64 become OFF. Furthermore, the voltage applied to the gate of the N-channel MOS transistor 66 becomes “H”, and the N-channel MOS transistor 66 becomes ON. As a result, the voltage applied to the gate of the P-channel MOS transistor 61 becomes “L”, and the P-channel MOS transistor 61 becomes ON. Eventually, the high voltage being “H” and supplied from the second power supply terminal 6 is output to the output terminal 8.

When the control signal at the control signal input terminal 4 is “L” and when the reset command signal serving as the output signal of the protection circuit 3 is “H”, by virtue of the logic circuit comprising the MOS inverters 51 and 54 and the AND circuits 52 and 53, the voltages applied to the gates of the N-channel MOS transistors 62 and 64 become “H”, and the N-channel MOS transistors 62 and 64 become ON. Furthermore, the voltage applied to the gate of the N-channel MOS transistor 66 becomes “L”, and the N-channel MOS transistor 66 becomes OFF. As a result, the voltage applied to the gate of the P-channel MOS transistor 61 becomes “H”, and the P-channel MOS transistor 61 becomes OFF. Eventually, the ground side voltage being “L” and supplied from the third power supply terminal 7 is output to the output terminal 8.

When the voltage at the first power supply terminal 5 lowers, the protection circuit 3 operates, and the output of the protection circuit 3 becomes “L”. At this time, the reset command signal serving as the output signal of the protection circuit 3 has priority, regardless of the state of the control signal at the control signal input terminal 4. The voltages applied to the gates of the N-channel MOS transistors 62 and 66 become “L”, and the N-channel MOS transistors 62 and 66 become OFF. Furthermore, the voltage applied to the gate of the N-channel MOS transistor 64 becomes “H”, and the N-channel MOS transistor 64 becomes ON. Hence, the P-channel MOS transistor 61 becomes OFF, and the N-channel MOS transistor 62 becomes OFF, whereby the state at the output terminal 8 is forcibly set to a high impedance state.

In the PDP driver 10A according to the second embodiment, since the pull-down resistor 9 is provided between the output of the protection circuit 3 and the third power supply terminal 7 on the ground side as shown in FIG. 6, the output of the protection circuit 3 is forcibly set to “L” using the pull-down resistor 9 when the power voltage rises abruptly. Hence, in the PDP driver 10A according to the second embodiment, the output of the protection circuit 3 securely becomes “L” in a transient state in which the power voltage rises abruptly, regardless of the state of the control signal at the control signal input terminal 4. Consequently, the output from the output terminal 8 can be prevented securely from becoming indefinite.

### Third Embodiment

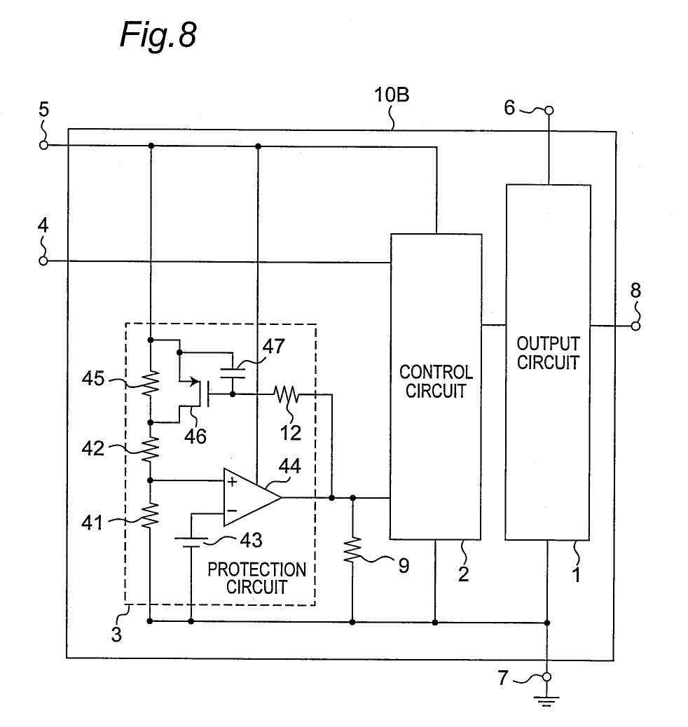

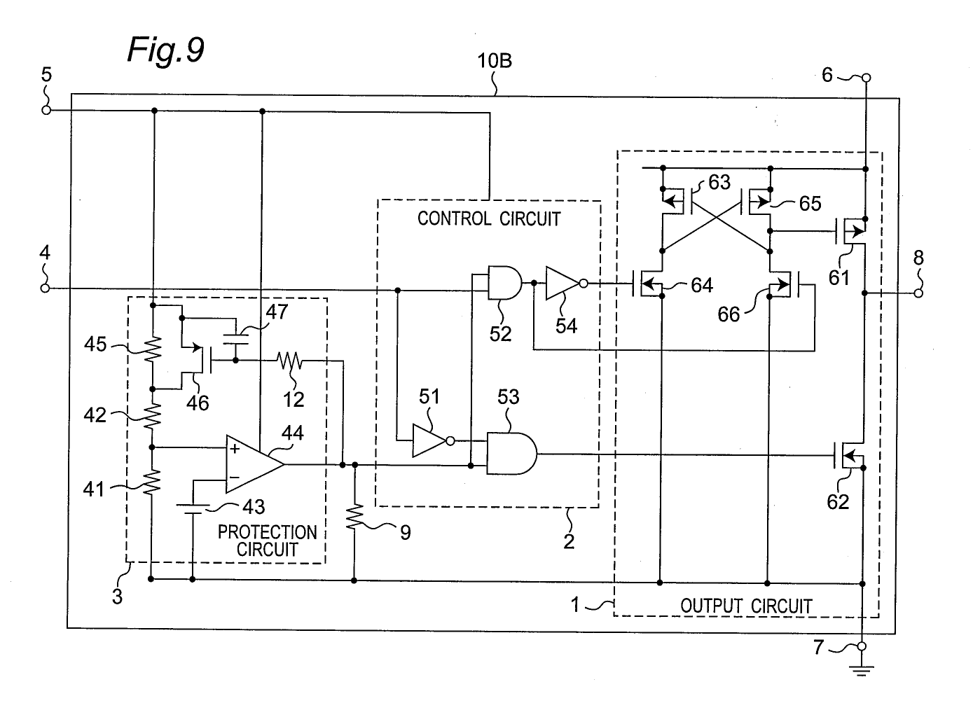

A semiconductor integrated circuit device according to a third embodiment of the present invention will be described below referring to FIGS. 8 and 9. FIG. 8 is a view showing the configuration of the semiconductor integrated circuit device according to the third embodiment of the present invention, and FIG. 9 is a circuit diagram of the semiconductor integrated circuit device shown in FIG. 8. The components having the same functions and configurations as those of the semiconductor integrated circuit devices according to the first embodiment and the second embodiment described above are designed by the same numerals, and their descriptions are omitted.

In the semiconductor integrated circuit device according to the first embodiment shown in FIG. 1 described above, in an operation state in which the power from the first power supply terminal 5 is abruptly turned ON, the output of the protection circuit 3 does not become Low level (L) but becomes High level (H) owing to the parasitic capacitance 47 across the source and the gate of the P-channel MOS transistor 46 in the protection circuit 3. As a result, there may occur a period during which the reset command signal is not output to the control circuit 2.

In the semiconductor integrated circuit device according to the third embodiment, to eliminate the above-mentioned adverse effect owing to the parasitic capacitance 47 across the source and the gate of the P-channel MOS transistor 46 of the protection circuit 3 configured as described above, a pull-down resistor is provided between the output of the protection circuit 3 and the third power supply terminal 7, as in the semiconductor integrated circuit device according to the second embodiment described above, and a resistor 12 is further provided between the gate of the P-channel MOS transistor 46 and the output of the protection circuit 3. In the semiconductor integrated circuit device according to the third embodiment configured as described above, when the power voltage from the first power supply terminal 5 rises abruptly, the adverse effect owing to the parasitic capacitance 47 across the source and the gate of the P-channel MOS transistor 46 in the protection circuit 3 can be eliminated. Hence when the power voltage from the first power supply terminal 5 rises abruptly, the output of the protection circuit 3 becomes Low level (L), and the reset command signal is output to the control circuit 2. As a result, even when the power voltage from the first power supply terminal 5 rises abruptly, the output from the output terminal 8 becomes stable without causing any malfunction in the semiconductor integrated circuit device according to the third embodiment.

The semiconductor integrated circuit device according to the third embodiment comprises two power supplies (a high-voltage power supply and a low-voltage power supply) and one ground side terminal. However, the circuit device can comprise one power supply and one ground side terminal. In this case, the power voltage at the first power supply terminal 5 is used as the power voltage that is input to the output circuit.

### Fourth Embodiment

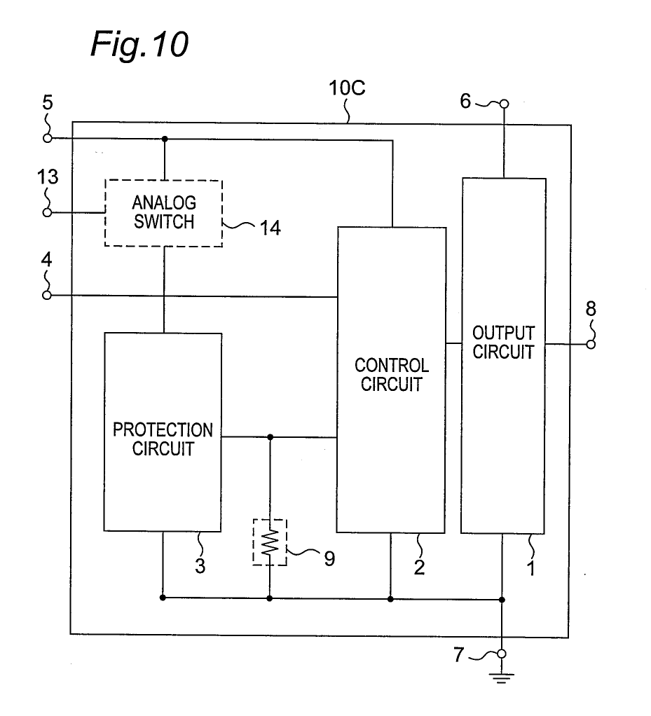

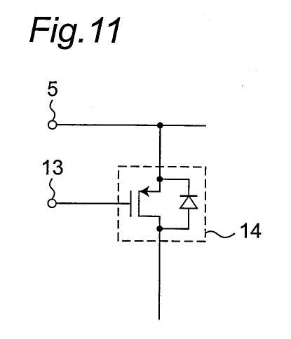

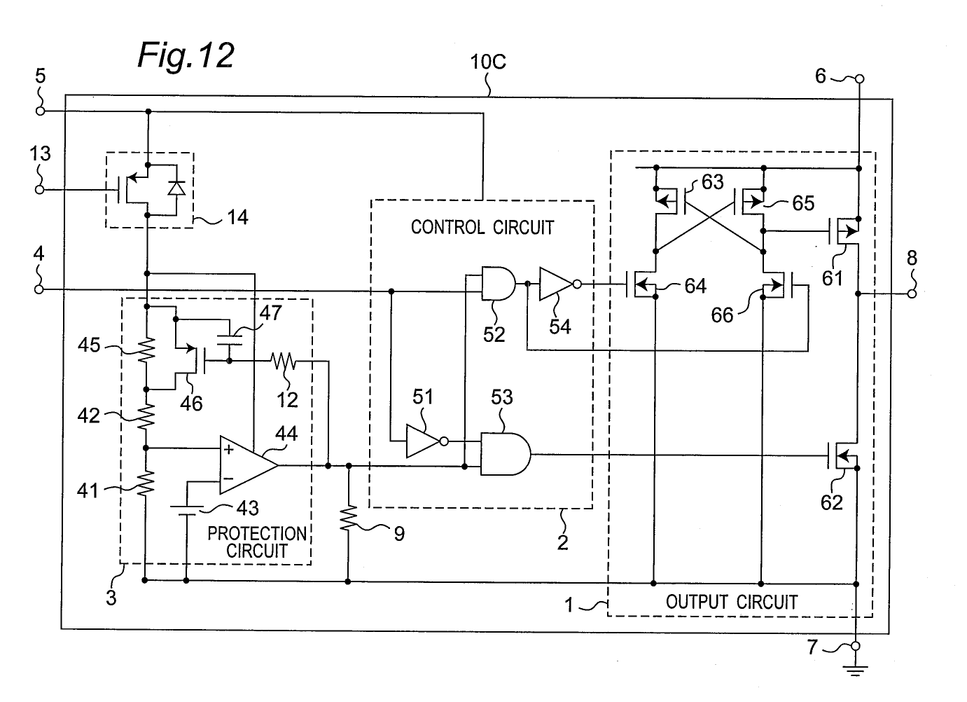

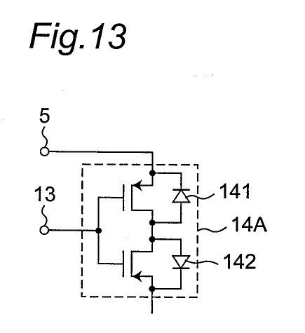

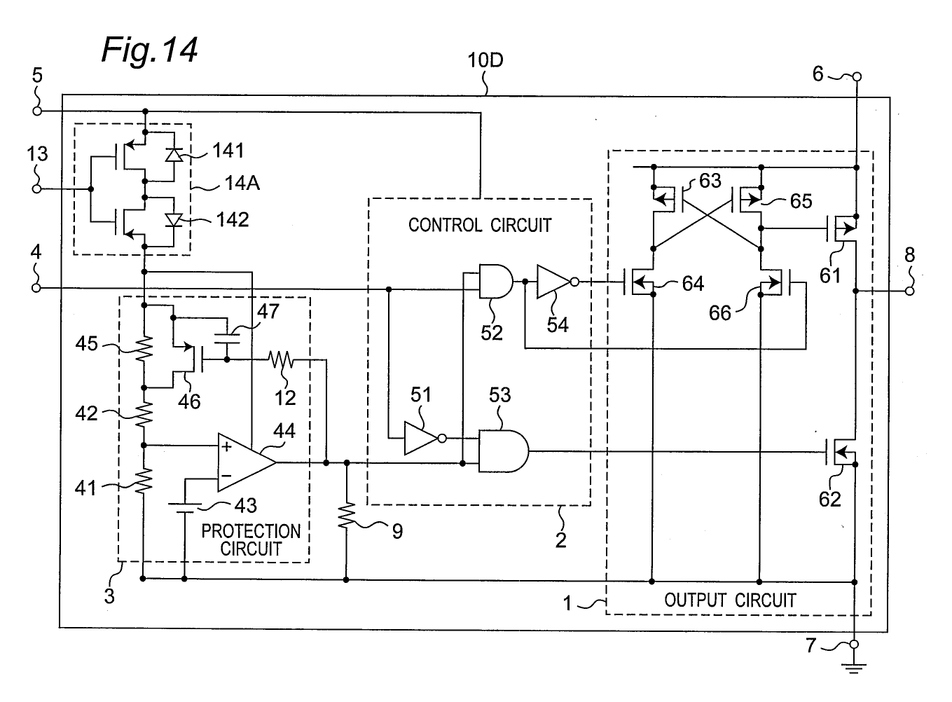

A semiconductor integrated circuit device according to a fourth embodiment of the present invention will be described below referring to FIGS. 10 and 14. FIG. 10 is a view showing the configuration of the semiconductor integrated circuit device according to the fourth embodiment of the present invention. FIG. 11 is a circuit diagram showing a specific configuration of an analog switch circuit in the semiconductor integrated circuit device according to the fourth embodiment. FIG. 12 is a circuit diagram showing a specific configuration of the semiconductor integrated circuit device provided with the analog switch circuit shown in FIG. 11. FIG. 13 is a circuit diagram showing another configuration of the analog switch circuit in the semiconductor integrated circuit device according to the fourth embodiment of the present invention. FIG. 14 is a circuit diagram showing a specific configuration of the semiconductor integrated circuit device provided with the analog switch circuit shown in FIG. 13.

The components having the same functions and configurations as those of the semiconductor integrated circuit devices according to the first embodiment to the third embodiment described above are designed by the same numerals, and their descriptions are omitted.

As shown in FIG. 10, the semiconductor integrated circuit device according to the fourth embodiment is obtained by providing an analog switch circuit 14 for the configuration of the semiconductor integrated circuit device according to the second embodiment. The semiconductor integrated circuit device according to the fourth embodiment is described as being configured such that the analog switch circuit 14 is provided for the semiconductor integrated circuit device according to the second embodiment. However, the analog switch circuit 14 can also be provided for the semiconductor integrated circuit device according to the third embodiment, and even this configuration has a similar effect.

The occurrence of an abnormal leak current in the control circuit 2 in the semiconductor integrated circuit devices results in defective semiconductor integrated circuit devices. For the purpose of securely preventing such defective semiconductor integrated circuit devices from being shipped from factories, the detection of the leak current in the control circuit 2 is an important inspection to be performed before shipment.

Inside a single semiconductor chip, the control circuit 2 and the protection circuit 3 are connected to the first power supply terminal 5, mutually connected electrically and integrated. When the current flowing steadily in the protection circuit 3 is compared with the leak current in the control circuit 2, the steady current flowing in the protection circuit 3 is approximately several hundreds of μA, and the leak current in the control circuit 2 is several nA. For this reason, it is difficult to securely detect the leak current in the control circuit 2 using an ordinary inspection method for semiconductor chips.

The semiconductor integrated circuit device according to the fourth embodiment has a configuration wherein the leak current in the control circuit 2 can be inspected easily and securely before product shipment, in addition to the effect in the semiconductor integrated circuit devices according to the embodiments described above that the protection circuit 3 operates stably even when abrupt power ON or OFF occurs.

As shown in FIG. 10, the semiconductor integrated circuit device 10C according to the fourth embodiment is provided with the analog switch circuit 14 between the first power supply terminal 5 and the protection circuit 3. Furthermore, the semiconductor integrated circuit device 10C is provided with a control terminal 13 to which a signal for ON/OFF controlling the analog switch circuit 14 is input.

FIG. 11 is a specific circuit diagram of the analog switch circuit 14 in the semiconductor integrated circuit device 10C according to the fourth embodiment. As the analog switch circuit 14 according to the fourth embodiment, a P-channel MOS transistor is used. The analog switch circuit 14 is provided to shut OFF the current flowing from the first power supply terminal 5 to the protection circuit 3 when the leak current in the control circuit 2 is inspected.

In the semiconductor integrated circuit device 10C according to the fourth embodiment, for the purpose of inspecting the leak current in the control circuit 2, the analog switch circuit 14 is set OFF, thereby shutting OFF the current flowing from the power supply terminal 5 to the protection circuit 3. For this purpose, in the analog switch circuit 14, the source of the P-channel MOS transistor is connected to the first power supply terminal 5, and the drain of the P-channel MOS transistor is connected to the power input side of the protection circuit 3. Furthermore, the gate of the P-channel MOS transistor is connected to the control terminal 13.

FIG. 12 is a circuit diagram of the semiconductor integrated circuit device 10C according to the fourth embodiment including the analog switch circuit 14 shown in FIG. 11. As shown in FIG. 12, the configuration of the semiconductor integrated circuit device 10C according to the fourth embodiment is the same as that of the third embodiment shown in FIG. 9 described above except for the analog switch circuit 14. Hence, in the operation state of the semiconductor integrated circuit device 10C according to the fourth embodiment, the protection circuit 3 is configured so as to detect the power voltage of the first power supply terminal 5 and so that there occurs no period during which the output of the output circuit 1 is indefinite.

In the operation state of the semiconductor integrated circuit device 10C according to the fourth embodiment configured as described above, the control terminal 13 is set Low level (L), and the P-channel MOS transistor of the analog switch circuit 14 is ON. In this state, current flows from the first power supply terminal 5 to the protection circuit 3, and the protection circuit 3 becomes active. As a result, in the operation state of the semiconductor integrated circuit device 10C according to the fourth embodiment, when the power voltage at the first power supply terminal 5 drops (lowers), the voltage variation at the first power supply terminal 5 is in a state of being detectable in the protection circuit 3.

On the other hand, in the state of inspecting the leak current in the control circuit 2 before product shipment, a High level (H) signal is input to the control terminal 13 to turn OFF the P-channel MOS transistor of the analog switch circuit 14. By the OFF setting of the analog switch circuit 14 as described above, the current flowing steadily between the first power supply terminal 5 and the third power supply terminal 7 can be shut OFF, and the leak current in the control circuit 2 is in a state of being detectable.

When the voltage at the third power supply terminal 7 on the ground side becomes high and when the voltage applied to the protection circuit 3 rises, current flows in the opposite direction, that is, from the protection circuit 3 to the first power supply terminal, and an overcurrent may flow to the control circuit 2 connected to the first power supply terminal 5. When the overcurrent flows to the control circuit 2 as described above, the control circuit 2 is in danger of being broken. To solve this kind of problem, the inventors have proposed an analog switch circuit 14A shown in FIG. 13. The analog switch circuit 14A will be described below.

FIG. 13 is a circuit diagram showing another configuration example of the analog switch circuit according to the fourth embodiment. The analog switch circuit 14A shown in FIG. 13 comprises two P-channel MOS transistors 141 and 142. The first power supply terminal 5 is connected to the source of the P-channel MOS transistor 141, one of the P-channel MOS transistors. The power supply side terminal of the protection circuit 3 is connected to the source of the other P-channel MOS transistor 142. The drains of the P-channel MOS transistors 141 and 142 are connected to each other. The gates of the P-channel MOS transistors 141 and 142 are connected to the input terminal 13.

FIG. 14 is a circuit diagram of a semiconductor integrated circuit device 10D serving as another configuration example of the fourth embodiment including the analog switch circuit 14A shown in FIG. 13. As shown in FIG. 14, the configuration of the semiconductor integrated circuit device 10D is the same as that of the third embodiment shown in FIG. 9 described above except for the analog switch circuit 14A. Hence, in the operation state of the semiconductor integrated circuit device 10D according to the fourth embodiment, the protection circuit 3 is configured so as to detect the power voltage of the first power supply terminal 5 and so that there occurs no period during which the output of the output circuit 1 is indefinite.

As shown in FIGS. 13 and 14, the analog switch circuit 14A comprises the P-channel MOS transistor 141 and the P-channel MOS transistor 142 connected thereto in the reverse direction. With the analog switch circuit 14A configured as described above, when the voltage at the third power supply terminal 7 on the ground side rises and when the voltage of the protection circuit 3 rises, any reverse current flowing from the protection circuit 3 to the first power supply terminal 5 can be prevented using the body diode of the P-channel MOS transistor 142. For this reason, in the semiconductor integrated circuit device 10D shown in FIG. 14, the leak current in the control circuit 2 can be inspected securely and accurately. Even when the voltage at the third power supply terminal 7 on the ground side becomes high and when the voltage applied to the protection circuit 3 rises, no overcurrent flows to the control circuit 2. It is therefore possible to provide a semiconductor integrated circuit device having high reliability. In the embodiments described above, a PDP driver is described as a semiconductor integrated circuit device. However, the technical concept of the present invention is not limited only to such a PDP driver but can be applied to circuits for driving apparatuses other than PDPs.

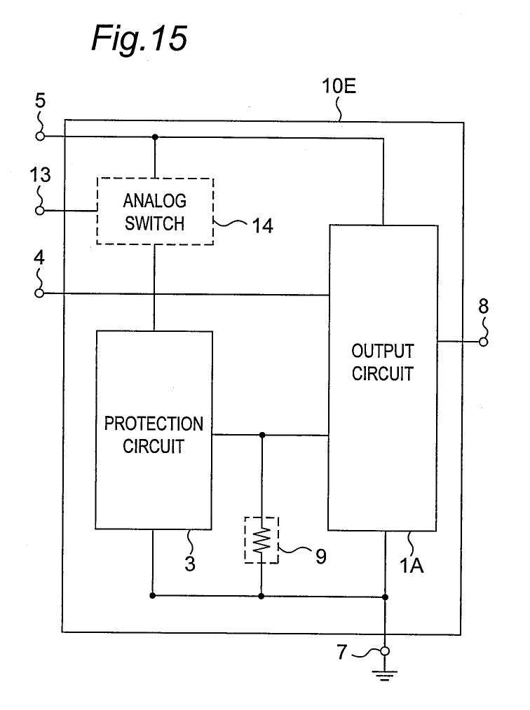

FIG. 15 is a block diagram showing still another configuration of the semiconductor integrated circuit device according to the fourth embodiment. As shown in FIG. 15, in the semiconductor integrated circuit device 10E, one power supply at the first power supply terminal 5 and one ground side terminal 7 constitute a power supply circuit. The semiconductor integrated circuit device 10E shown in FIG. 15 has the functions of the control circuit 2 and the output circuit 1 shown in FIG. 10. The output circuit 1A thereof having the functions of the control circuit 2 and the output circuit 1 is driven using the voltage supplied from the first power supply terminal 5, and a desired signal is output from the output terminal 8. Configuring a power supply circuit using one power supply and one ground side terminal in the semiconductor integrated circuit device as described above is also possible similarly in the above-mentioned embodiments according to the present invention.

With the present invention, the protection circuit of the semiconductor integrated circuit device operates securely and prevents any overcurrent owing to the simultaneous ON operation of the transistors constituting the push-pull circuit in the output circuit, thereby being capable of preventing the semiconductor integrated circuit device from being broken. In addition, the steady current flowing in the protection circuit of the semiconductor integrated circuit device according to the present invention is shut OFF securely, whereby any abnormal leak current in the control circuit can be detected accurately at the time of shipping inspection. In the semiconductor integrated circuit device according to the present invention, the high-voltage output does not malfunction. For this reason, the present invention has a particularly excellent effect in the field of semiconductor integrated circuit devices for driving plasma display panels (PDPs), for example.

As described above, in the semiconductor integrated circuit device according to the present invention, the output from the output circuit can be prevented securely from becoming indefinite when power is turned ON or OFF or in a transient state in which the power voltage varies abruptly.

In addition, in the semiconductor integrated circuit device according to the present invention, a resistor is provided between the output of the protection circuit operating at low voltage and the ground side terminal, whereby any period during which the output of the protection circuit becomes indefinite is eliminated when power is turned ON or OFF, or in a transient state in which the power voltage varies abruptly. Hence, the output of the output circuit can be set to a high impedance state immediately.

Furthermore, in the semiconductor integrated circuit device according to the present invention, a resistor is provided between the gate of the P-channel MOS transistor serving as a hysteresis generating circuit inside the protection circuit and the output of the protection circuit, thereby being capable of preventing improper operation of the protection circuit owing to the parasitic capacitance across the source and the gate of the P-channel MOS transistor serving as a hysteresis generating circuit when power is abruptly supplied from the first power supply terminal.

Besides, in the semiconductor integrated circuit device according to the present invention, an analog switch circuit having a P-channel MOS transistor for shutting OFF the protection circuit is provided, whereby the leak current in the control circuit can be inspected accurately.

Still further, in the semiconductor integrated circuit device according to the present invention, an analog switch circuit having two P-channel MOS transistors is provided between the first power supply terminal and the protection circuit to prevent any reverse current from flowing from the protection circuit to the first power supply terminal, whereby the accuracy of inspecting the leak current in the control circuit is improved further.

The present invention relates to a semiconductor integrated circuit device having a protection circuit for stabilizing the output and is useful for semiconductor integrated circuit devices being used as circuits for driving plasma display panels (PDPs) and the like in particular.

What is claimed is:

1. A semiconductor integrated circuit device comprising:
a protection circuit for comparing a power voltage from a first power supply terminal with a reference voltage, for detecting power ON, power OFF and power voltage variation and for outputting a reset command signal so that the output at an output terminal has a high impedance at the time of power ON, power OFF and power voltage variation;
a control circuit, connected to said first power supply terminal, for receiving said reset command signal from said protection circuit and a control signal from a control signal input terminal and for generating drive signals; and
an output circuit, having a push-pull circuit and a level shift circuit comprising multiple MOS transistors and driven using said drive signals from the control circuit, for generating an output signal from said output terminal, wherein
said protection circuit, said control circuit and said output circuit are integrated in a single semiconductor chip.

2. The semiconductor integrated circuit device according to claim 1, wherein said protection circuit is connected between said first power supply terminal and a ground side terminal and has a voltage division circuit formed of multiple resistors for dividing the power voltage of said first power supply terminal, a comparator for comparing the divided voltage being input thereto with said reference voltage inside said protection circuit, and a hysteresis generating circuit connected across both terminals of at least one resistor of said voltage division circuit, the output of said comparator serving as a reset command signal.

3. The semiconductor integrated circuit device according to claim 2, wherein said division circuit comprises at least a first resistor, a second resistor and a third resistor, one terminal of said first resistor is connected to said ground side terminal, one terminal of said third resistor is connected to said first power supply terminal, the comparator compares the voltage of the connection point of said first resistor and said second resistor with said reference voltage inside said protection circuit, and said hysteresis generating circuit comprises a P-channel MOS transistor, the source of which is connected to said first power supply terminal, the drain of which is connected to the connection point of said second resistor and said third resistor, and the gate of which is connected to the output of said comparator.

4. The semiconductor integrated circuit device according to claim 1, wherein said output circuit is connected to a second power supply terminal having a voltage higher than that of said first power supply terminal.

5. The semiconductor integrated circuit device according to claim 1, wherein a resistor having a predetermined resistance value is provided between the output of said protection circuit and said ground side terminal.

6. The semiconductor integrated circuit device according to claim 2, wherein the reference voltage that is input to said comparator has the threshold value of an N-channel MOS transistor, the drain and gate of which are connected to each other.

7. The semiconductor integrated circuit device according to claim 3, wherein a resistor is provided between the gate of the P-channel MOS transistor of said hysteresis generating circuit and the output of said comparator.

8. The semiconductor integrated circuit device according to claim 1, wherein an analog switch circuit having a control terminal is provided between said first power supply terminal and the power input side of said protection circuit.

9. The semiconductor integrated circuit device according to claim 8, wherein said analog switch circuit comprises a P-channel MOS transistor, the source of which is connected to said first power supply terminal, the drain of which is connected to the power input side of said protection circuit, and the gate of which is connected to said control terminal.

10. The semiconductor integrated circuit device according to claim 8, wherein said analog switch circuit comprises two P-channel MOS transistors, the source of a first P-channel MOS transistor is connected to said first power supply terminal, the drain of said first P-channel MOS transistor is connected to the drain of a second P-channel MOS transistor, the source of said second P-channel MOS transistor is connected to the power input side of said protection circuit, the gates of said first P-channel MOS transistor and said second P-channel MOS transistor are connected to said control terminal.
